(19) United States
(12) Patent Application Publication
(10) Pub. No.: US 2025/0166991 A1
(43) Pub. Date: May 22, 2025

(54) WAFER BOW COMPENSATION BY PATTERNED UV CURE

(71) Applicant: Lam Research Corporation, Fremont, CA (US)

(72) Inventors: Tong LEI, Shanghai (CN); Yushan CHI, Shanghai (CN); Jiang YU, Shanghai (CN)

(21) Appl. No.: 18/840,480

(22) PCT Filed: Feb. 10, 2023
(86) PCT No.: PCT/US2023/012800

§ 371 Date: Aug. 21, 2024

Related U.S. Application Data
(60) Provisional application No. 63/268,660, filed on Feb. 28, 2022.

(51) Int. Cl. H01L 21/02; G03F 7/00; G03F 7/20

(52) U.S. Cl. CPC H01L 21/02348; G03F 7/2004; G03F 7/2045; G03F 7/70875

(57) ABSTRACT

UV light may be directed through a patterned window to cause selective UV exposure of certain areas of a substrate. A stress-tunable film deposited on the substrate may undergo localized stress changes from selective UV exposure. Localized stress changes in the stress-tunable film may mitigate wafer bowing in the substrate. The patterned window may be designed with UV-transparent regions and UV-non-transparent regions to facilitate targeted UV exposure of the stress-tunable film. In some implementations, the patterned window may include a metal coating, a ceramic cover, or a metal cover for selective UV exposure. In some implementations, the patterned window may further include transition regions that permit partial transmission of UV light to limit stress changes in corresponding areas of the stress-tunable film.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor manufacturing processes involve many deposition and etching operations, which can change wafer bow drastically. For example, in 3D-NAND fabrication, which is gradually replacing 2D-NAND chips due to lower cost and higher reliability in various applications, multi-stacked films with thick, high stress carbon-based hard masks and/or metallization lines can cause significant wafer warpage, leading to front side lithographic overlay mismatch, or even wafer bow beyond chucking limit of an electrostatic chuck.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is an apparatus for selective UV exposure. The apparatus includes an ultraviolet (UV) light source and a process chamber. The process chamber includes a substrate support configured to support a semiconductor substrate, where the semiconductor substrate comprises a stress-tunable film, and one or more heating elements configured to control a temperature of the semiconductor substrate. The apparatus further includes a window positioned between the substrate support and the UV light source, where the window is patterned with one or more UV-transparent regions for selectively exposing one or more first regions of the stress-tunable film to UV light and one or more UV-non-transparent regions for selectively blocking one or more second regions of the stress-tunable film from UV light.

In some implementations, the window is patterned with a metal coating corresponding to the one or more UV-non-transparent regions. In some implementations, the metal coating comprises silver, aluminum, or combinations thereof. In some implementations, the window is patterned with a ceramic cover disposed on the window and corresponding to the one or more UV-non-transparent regions. In some implementations, the ceramic cover comprises aluminum nitride or aluminum oxide. In some implementations, the window is patterned with a metal cover disposed on the window and corresponding to the one or more UV-non-transparent regions. In some implementations, the window is further patterned with one or more transition regions lining an interface between the one or more UV-transparent and the one or more UV-non-transparent regions, where the one or more transition regions are semi-transparent to UV light or comprise a grid-like pattern of UV-transparent and UV-non-transparent materials. In some implementations, the one or more transition regions comprise a metal layer having a thickness less than about 100 nm. In some implementations, the one or more transition regions are configured to provide a more graduated stress change at interfaces between the one or more first regions of the stress-tunable film and the one or more second regions of the stress-tunable film. In some implementations, the one or more UV-transparent regions are configured to induce a stress shift in an amount equal to or greater than about 50% in the one or more first regions of the stress-tunable film. In some implementations, the UV light source is configured to direct UV light to a backside of the semiconductor substrate, where the stress-tunable film is formed on the backside of the semiconductor substrate. In some implementations, the UV light source is configured to direct UV light to a frontside of the semiconductor substrate, wherein the stress-tunable film is formed on the frontside of the semiconductor substrate. The apparatus further includes a controller configured with instructions to perform the following operations: provide the semiconductor substrate in the process chamber, and selectively expose the one or more first regions of the stress-tunable film to UV light using the window that is patterned so as to locally modulate stress on the stress-tunable film. In some implementations, the stress-tunable film comprises silicon nitride, silicon oxide, silicon oxynitride, or silicon carbonitride, and the window comprises quartz.

Also provided herein is a method of selective UV exposure. The method includes providing a semiconductor substrate on a substrate support in a process chamber, where the semiconductor substrate comprises a stress-tunable film, where a quartz window is positioned between the process chamber and an ultraviolet (UV) light source, where the quartz window is patterned with one or more UV-transparent regions and one or more UV-non-transparent regions. The method further includes selectively exposing one or more first regions of the stress-tunable film to UV light through the one or more UV-transparent regions of the quartz window and selectively blocking one or more second regions of the stress-tunable film from UV light by the one or more UV-non-transparent regions of the quartz window.

In some implementations, selectively exposing the one or more first regions of the stress-tunable film comprises locally modulating stress in the one or more first regions of the stress-tunable film. In some implementations, the quartz window is patterned with a metal coating corresponding to the one or more UV-non-transparent regions. In some implementations, the quartz window is patterned with a ceramic cover or metal cover disposed on the quartz window and corresponding to the one or more UV-non-transparent regions. In some implementations, the quartz window is further patterned with one or more transition regions between the one or more UV-transparent and the one or more UV-non-transparent regions, where the one or more transition regions are semi-transparent to UV light. In some implementations, the one or more transition regions comprise a metal layer having a thickness less than about 100 nm.

### BRIEF DESCRIPTION OF THE DRAWINGS

FIG. 1 shows a perspective view of a bowed semiconductor substrate illustrating wafer bowing in an x-axis direction and a y-axis direction.

FIG. 2 shows a top view schematic diagram of an example system for mitigating wafer bowing using a zoning mask adjacent to a semiconductor substrate.

FIG. 3 shows a top view schematic diagram of an example system for mitigating wafer bowing using a multi-plenum showerhead.

FIG. 4A shows a schematic diagram of an example apparatus for UV treatment, the apparatus comprising a window positioned between a UV source and a semiconductor substrate.

FIG. 4B shows a top view of the window transparent to UV radiation of FIG. 4A.

FIG. 5A shows a schematic diagram of an example apparatus for UV treatment, the apparatus comprising a patterned window positioned between a UV source and a semiconductor substrate according to some implementations.

FIG. 5B shows a cross-sectional schematic illustration of the patterned window of FIG. 5A having a metal coating according to some implementations.

FIG. 5C shows a cross-sectional schematic illustration of the patterned window of FIG. 5A having a ceramic cover according to some implementations.

FIG. 6A shows a top view schematic diagram of a patterned window having UV-transparent and UV-non-transparent regions according to some implementations.

FIG. 6B shows a top view schematic diagram of a patterned window having UV-transparent that occupy a larger surface area than UV-non-transparent regions according to some implementations.

FIG. 6C shows a top view schematic diagram of a patterned window having UV-transparent regions, UV-non-transparent regions, and transition regions that are semi-transparent to UV radiation according to some implementations.

FIG. 6D shows a top view schematic diagram of a patterned window having UV-transparent regions, UV-non-transparent regions, and transition regions made of a grid-like mesh according to some implementations.

FIG. 7 shows a schematic diagram of an example apparatus for UV backside treatment, the apparatus comprising a patterned window positioned between a UV source and a semiconductor substrate according to some implementations.

FIG. 8 illustrates a flow diagram of an example method of selective UV exposure according to some implementations.

FIG. 9 illustrates a schematic diagram of an example apparatus for selective UV exposure of a stress-tunable film according to some implementations.

FIG. 10 illustrates a schematic diagram of an example process tool for performing operations of selective UV exposure according to some implementations.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials.

Semiconductor fabrication processes involve formation of various structures, many of which may be two-dimensional. As semiconductor device dimensions shrink and devices are scaled to be smaller, the density of features across a semiconductor substrate increases, resulting in layers of material etched and deposited in various ways, including in three dimensions. For example, 3D-NAND is one technology that is becoming increasingly popular due to lower cost and increased memory density compared to other techniques, such as 2D-NAND, and higher reliability in various applications. During the fabrication of a 3D-NAND structure, wafer bow can change drastically. For example, deposition of thick hard mask materials and etching of trenches along a wafer surface in fabricating a 3D-NAND structure can cause wafer bowing.

As layers of films are stacked on top of each other during fabrication, more stress is introduced to the semiconductor wafer which can cause bowing. The bowing can have various shapes. In a concave-shaped wafer, sometimes referred to as a “smiling wafer” or a bow-shaped wafer, the lowest point is the center of the wafer and the highest point is the edge of the wafer. In a convex-shaped wafer, sometimes referred to as a “sad wafer” or dome-shaped wafer, the lowest point is the edge of the wafer and the highest point is the center of the wafer.

Bowing can be measured using an optical technique. Wafer bowing can be measured or evaluated by obtaining a wafer map or stress map. Bowing can be quantified using a bow value or warpage value as described herein, which is measured as the vertical distance between the lowest point of the semiconductor wafer to the highest point on the wafer. The warpage value can be along one or more axes—for example, an asymmetrically warped wafer may have an x-axis warpage and/or a y-axis warpage.

In a bow-shaped wafer, the lowest point is the center of the wafer and the highest point is the edge of the wafer. In a dome-shaped wafer, the lowest point is the edge of the wafer and the highest point is the center of the wafer. Bow-shaped and dome-shaped wafers have symmetrical or largely symmetrical bowing. Wafers can also have asymmetric bowing. In asymmetric bowing, warpage is measured along an x-axis and a y-axis. An asymmetrically bowed wafer has different values for the x-axis warpage and y-axis warpage. In some cases, an asymmetrically bowed wafer has a negative x-axis warpage and a positive y-axis warpage. In some cases, an asymmetrically bowed wafer has a positive x-axis warpage and a negative y-axis warpage. In some cases, an asymmetrically bowed wafer has both a positive x-axis warpage and a positive y-axis warpage, but the warpage values are different. In some cases, an asymmetrically bowed wafer has both a negative x-axis warpage and a negative y-axis warpage, but the warpage values are different. One example of an asymmetrically bowed wafer is a saddle-shaped wafer. For a saddle-shaped wafer, in one example, the warpage on the x-axis may be +200 μm and the warpage on the y-axis may be −200 μm. Saddle-shaped wafers have two opposing edges of the wafer that are curved upward while another two opposing edges of the wafer are curved downward. As used herein, warpage can refer to any deviation from planarity exhibited by a wafer, where a bow-shaped wafer, dome-shaped wafer, and saddle-shaped wafer are examples of different types of warpage in a wafer.

Bowing can cause numerous problems with subsequent processing if the substrate is warped. For example, during lithography, etching can be uneven if the substrate is warped. This can lead to problems associated with defocus and overlay degradation, which can lead to major yield loss. High bowing can be caused by deposition of thick, high stress hard mask layer. Additionally, due to multi-stacked films and the presence of thick, high stress hard masks used in such fabrication processes, etching can cause some asymmetric warpage and deposition processes can introduce significant wafer warpage of up to a variation between +500 μm to −1300 μm bow. For example, an ashable hard mask may have a stress value of up to −1000 MPa and have a bow value of up to −1000 μm. In some cases, a high aspect ratio slit etch and metal fill (e.g., tungsten fill) can induce large anisotropic stress on the semiconductor substrate.

Addressing such wafer warpage can be a challenge as subsequent or downstream processing may be affected by a wafer warpage exceeding ±200 μm, exceeding ±300 μm or exceeding ±500 μm. For instance, mechanical wafer handling may be affected due to wafer warpage, where wafers that are not flat may not be gripped or held effectively by a wafer robot or wafer handling mechanism. Additionally, wafer warpage may contribute to process non-uniformity, where downstream etch, deposition, or clean operations may be adversely affected due to processing non-uniformities across a surface of the wafer. In some cases, processing of highly warped wafers may cause further warping. For example, etching of a trench in one direction can cause warping in asymmetric bowing due to asymmetric stress on the wafer. Moreover, lithography operations may be adversely affected by wafer warpage as precise patterns are unable to be formed. When wafers are used in subsequent processing that involve chucking of the wafer to an electrostatic chuck, highly warped wafers may not be processed in some tools. Many electrostatic chucks have a “chucking limit,” which is defined as the maximum warpage tolerated before the wafer cannot be effectively chucked. For example, some electrostatic chucks have a chucking limit of about ±300 μm. Warped wafers that exceed the chucking limit may not be processed in such instances.

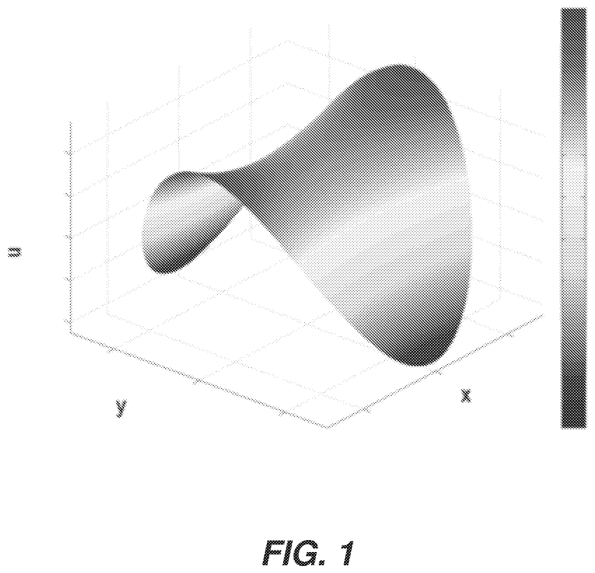

FIG. 1 shows a perspective view of a bowed semiconductor substrate illustrating wafer bowing in an x-axis direction and a y-axis direction. The bowed semiconductor substrate is superimposed in a three-dimensional (3-D) coordinate system, with a reference plane of the bowed semiconductor substrate defined by the x-axis direction and y-axis direction, and with the u-axis indicative of warpage. As shown in FIG. 1, the bowed semiconductor substrate is asymmetrically bowed, meaning that the values for x-axis warpage and y-axis warpage are different. This creates bowing that is saddle-shaped. As discussed above, warpage refers to any deviation from planarity exhibited by a semiconductor substrate, where a saddle-shaped wafer represents an example of warpage in a semiconductor substrate.

As 3D-NAND technologies continue to scale up and high-aspect ratio features become increasingly more common, new challenges are emerging related to localized stress and inter-die stress variations on semiconductor substrates. Localized stress and inter-die stress variations may lead to block-bending, cell cross-talk, cell loss, and/or cell misalignments. Localized stress refers to stress changes that occur within a wafer in a non-uniform manner. Poorly compensated/corrected localized stress may lead to localized wafer topology changes, which in turn may lead to poor alignment during lithography. Such poor alignment is typically viewed in terms of in-plane distortion (IPD), which is a quantification of the vector displacement of on-wafer alignment marks from their expected positions due to wafer topology. High IPD during lithography may lead to undesirable changes in critical dimensions or any other feature that is defined in a lithographic step, and so the foregoing phenomena of block-blending, cell cross-talk, cell loss, and/or cell misalignments can arise due to lithographic errors.

Some techniques exist for addressing symmetric bowing of semiconductor wafers, and in some cases, techniques can be used to reduce warpage by changing the process for fabricating the desired layers in the substrate. A technique used for addressing symmetric bowing of semiconductor substrates can involve deposition of a bow compensation layer on a backside of a semiconductor substrate. Application of a bow compensation layer on the backside of a semiconductor substrate has largely been limited to monotonic global wafer warpage mitigation. In other words, such techniques for addressing bowing of semiconductor substrates have been mostly limited to techniques that are axially symmetric or multi-axially symmetric. However, few techniques exist for addressing asymmetric bowing such as saddle-shaped bowing. The complexity of current technologies leads to more complex wafer bowing shapes such as saddle-shaped bowing.

Of the few techniques for addressing asymmetric bowing, one such technique may involve precursor zoning masks provided adjacent to the backside of a bowed semiconductor substrate. For instance, a carrier ring supporting the bowed semiconductor substrate may be designed with a carrier ring mask for masking certain regions of the bowed semiconductor substrate during deposition. Another technique may involve a multi-plenum showerhead to control delivery of gas to different locations. For example, precursor material for depositing compressive films may be delivered through first zones of the showerhead pedestal and precursor material for depositing tensile films may be delivered through second zones of the showerhead pedestal.

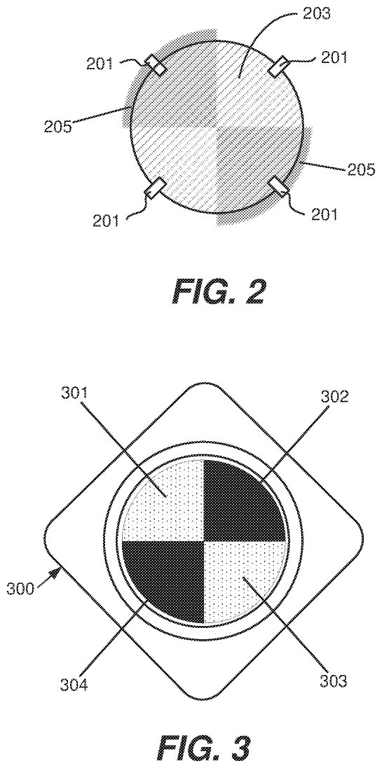

FIG. 2 shows a top view schematic diagram of an example system for mitigating wafer bowing using a zoning mask adjacent to a semiconductor substrate. A semiconductor substrate 203 may be provided in a process chamber. The semiconductor substrate 203 may be held by substrate holders 201 in the process chamber. A zoning mask 205 is positioned between the semiconductor substrate 203 and a gas distributor (e.g., showerhead pedestal) (not shown). The zoning mask 205 may shield or block certain regions of the semiconductor substrate 203 during deposition. For purposes of illustration, the zoning mask 205 is depicted as being transparent to show the semiconductor substrate 203 underlying the zoning mask 205. Only top right and bottom left quadrants of the semiconductor substrate 203 are exposed to the depositing species. In some implementations, the zoning mask 205 may be a circular, planar block of material divided into four quadrants. The top right and bottom left quadrants of the zoning mask 205 are exposed, and the top left and the bottom right quadrants of the zoning mask 205 are unexposed.

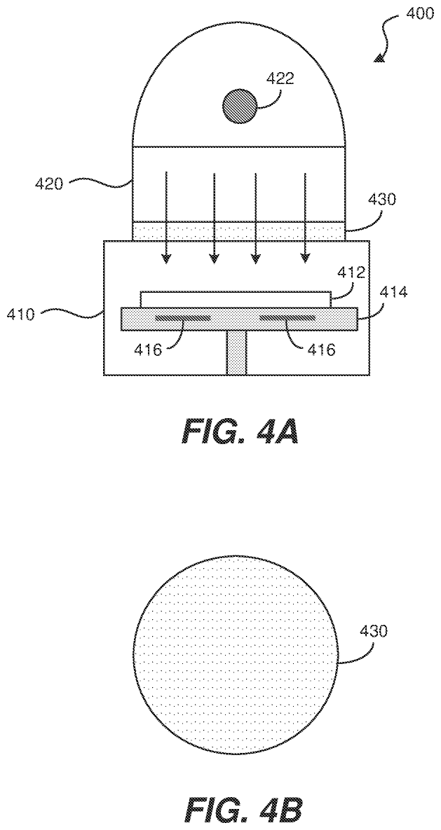

FIG. 3 shows a top view schematic diagram of an example system for mitigating wafer bowing using a multi-plenum showerhead. A showerhead 300 may be divided into four zones or regions 301, 302, 303, 304, each region capable of delivering different or same gases for forming different or same materials. In FIG. 3, regions 301 and 303 are “opposite regions” and regions 302 and 304 are “opposite regions.” For deposition of a bow compensation layer on an asymmetrically bowed semiconductor substrate, gases delivered to a first set of opposite regions (e.g., regions 301 and 303) may be the same, while gases delivered to a second set of opposite regions (e.g., regions 302 and 304) may be the same. However, gases delivered between the first set and second set may be different. By way of illustration, gases for depositing a compressive silicon oxide film may be delivered through the first set of opposite regions and gases for depositing a tensile silicon nitride film may be delivered through the second set of opposite regions.

Localized stress modulation may be achieved by delivering precursor material to certain areas or regions of bowed semiconductor substrate using a zoning mask as shown in FIG. 2. Localized stress modulation may be achieved using precursor zoning employing multiple plenums to control the delivery of gas to different locations as shown in FIG. 3. However, such techniques have been limited or ineffective due to high IPD overlay and problems associated with chucking the semiconductor substrate. Issues of high overlay error and vacuum chucking may be a result of sharp transitions of film stress between zones and the difficulty in designing a zone layout that minimizes local topography variation.

The present disclosure provides methods and apparatuses for mitigating asymmetric bowing in a bowed semiconductor substrate by selective UV exposure. Rather than separately depositing a compressive film and a tensile film in different regions of the bowed semiconductor substrate, a single compressive or tensile film is deposited on a frontside or backside of the bowed semiconductor substrate. The compressive or tensile film is a stress-tunable film that undergoes stress modulation from UV exposure. A UV chamber is equipped with a UV light source, a substrate support for supporting the bowed semiconductor substrate, and a window positioned between the substrate support and the UV light source. The window is patterned with UV-transparent regions and UV-non-transparent regions to permit selective exposure of certain areas of the stress-tunable film to undergo stress changes. In some implementations, the window is patterned with a metal coating or ceramic cover. In some implementations, the window is further patterned with transition regions that permit partial transmission of UV light so that corresponding areas of the stress-tunable film undergo partial stress changes.

As used herein, a substrate support is configured to hold, retain, or otherwise support a substrate in a processing chamber. The substrate is placed or provided on the substrate support during various processing steps performed in the processing chamber. As such, the substrate such as a semiconductor wafer is arranged on the substrate support in the UV chamber as the substrate undergoes processing (e.g., UV exposure). In some implementations, the substrate support is a pedestal (e.g., ceramic pedestal), an electrostatic chuck, a mechanical chuck, a plate, or other type of substrate support.

As used herein, a window is a piece of material between the substrate support and the UV light source, or a piece of material that separates a UV light chamber from a substrate processing chamber, where the piece of material is transmissive or at least partially transmissive to UV radiation. Generally, the window is made of a glass material such as quartz glass. In some implementations, the glass material is a quartz glass, borosilicate glass, or phosphate glass.

As used herein, UV radiation or UV light may broadly include radiation from 150 nm to the infrared region (about 1-10 μm). In some implementations, UV radiation or UV light is between about 150 nm and about 800 nm. UV radiation or UV light may be emitted in a range or in a single wavelength from the UV source.

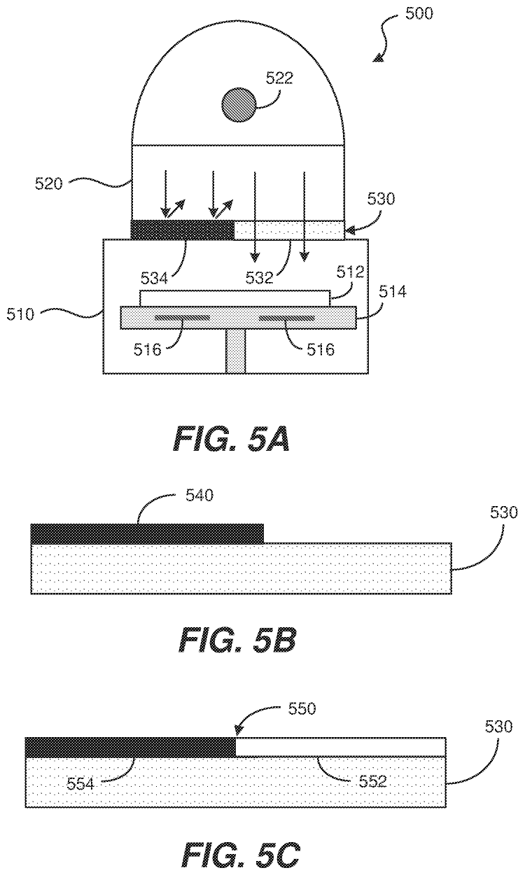

FIG. 4A shows a schematic diagram of an example apparatus for UV treatment, the apparatus comprising a window positioned between a UV source and a semiconductor substrate. FIG. 4B shows a top view of the window transparent to UV radiation of FIG. 4A. The apparatus 400 includes a process chamber 410 for treating or processing a substrate 412, and a UV light chamber 420 for housing a UV light source 422. The apparatus 400 includes a substrate holder 414 for supporting the substrate 412 in the process chamber 410. The apparatus 400 may include one or more heating elements 416 for controlling a temperature of the substrate 412. In some implementations, the substrate holder 414 may be a pedestal equipped with the one or more heating elements 416 for controlling the temperature of the substrate 412. In some implementations, the substrate 412 may make full contact with the pedestal or the substrate 412 may be supported above the pedestal by an attachment (e.g., pin). In some implementations, the substrate holder 414 may clamp or hold the substrate 412 so that a backside or frontside of the substrate 412 faces the UV light source 422. The substrate 412 may be a bowed semiconductor substrate, where the bowed semiconductor substrate may have a stress-tunable film (not shown) deposited on the backside or frontside of the bowed semiconductor substrate. The UV light source 422 may be configured to emit UV light to cure the stress-tunable so that the stress-tunable film undergoes stress changes.

The UV light source 422 may be any suitable illumination source that transmits UV radiation. The UV light source 422 may include a lamp, a light emitting diode (LED), a bulb, a laser, or a combination thereof. In some cases, the UV light source 422 may emit UV light across a broad band of wavelengths from 170 nm to 400 nm, or may emit UV light across a narrower band of wavelengths from 185 nm to 255 nm. For instance, the UV light source 422 may involve broadband UV light sources. The UV light source 422 and/or UV light chamber 420 may be equipped with apertures and beam-shaping optics such as lenses or mirrors. For example, the UV light chamber 420 may include cold mirrors for reflecting UV radiation. The UV light source 422 and/or UV light chamber 420 may be equipped with filters, reflectors, gratings, prisms, or other wavelength selection optics. For example, when the UV light source 422 is a broadband UV light source, which generates radiation in a broad spectrum, optical components such as reflectors, filters, or a combination of reflectors and filters may be used to modulate the part of the broad spectrum that reaches the substrate 412.

The apparatus 400 further includes a window 430 positioned between the UV light source 422 and the substrate holder 414. The window 430 may separate the UV light chamber 420 from the process chamber 410. The window 430 may be a quartz window that is transparent or at least substantially transparent to UV radiation. By changing the level of metal impurities and water content in a quartz window, the window 430 can be made to block radiations of undesired wavelengths. High-purity silica quartz with very little metal impurity is more transparent deeper into the ultraviolet spectrum. As an example, quartz with a thickness of 1 cm will have a transmittance of about 50% at a wavelength of 170 nm, which drops to only a few percent at 160 nm. Increasing levels of impurities in the quartz cause transmission of UV at lower wavelengths to be reduced. Electrically fused quartz has a greater presence of metallic impurities, limiting its UV transmittance wavelength to around 200 nm and longer. Synthetic silica, on the other hand, has much greater purity and will transfer down to 170 nm. For infrared radiation, the transmittance through quartz is determined by the water content. More water in the quartz means that infrared radiation is more likely absorbed. The water content in the quartz may be controlled through the manufacturing process. Thus, the spectrum of radiation transmission through the window 430 may be controlled to cut off or reduce UV transmission at shorter wavelengths and/or reduce infrared transmission at longer wavelengths. In FIGS. 4A and 4B, the window 430 is un-patterned so that all or substantially all of the UV light from the UV light chamber 420 passes through the window 430 into the process chamber 410.

The process chamber 410 may be equipped for controlling a temperature of the substrate 412. The one or more heating elements 416 may face the substrate 412 for substrate temperature control. As used herein, “heating elements” are used to control a workpiece or substrate temperature. Heating elements may be embedded in the substrate holder 414, positioned adjacent to the substrate 412, positioned inside the process chamber 410, or positioned outside the process chamber 410 for heating the substrate 412. In some embodiments, the one or more heating elements 416 may be one or more LEDs, where the LEDs may be arranged in a plurality of independently controllable heating zones. The independently controllable heating zones facilitate temperature control in varying regions of the substrate 412. In some embodiments, the one or more heating elements 416 are electrically resistive heaters. The one or more heating elements 416 are configured to control a temperature of the substrate 412, where the one or more heating elements 416 may permit substrate temperature control at a range between about 5° C. and about 675° C., or between about 50° C. and about 500° C.

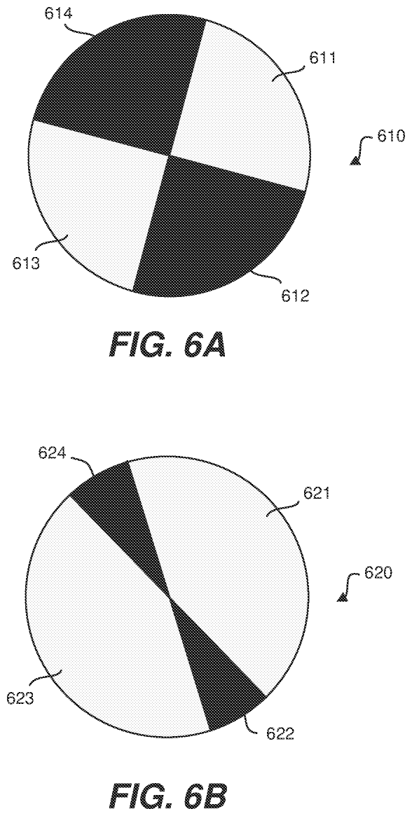

FIG. 5A shows a schematic diagram of an example apparatus for UV treatment, the apparatus comprising a patterned window positioned between a UV source and a semiconductor substrate according to some implementations. The apparatus 500 includes a process chamber 510 for treating or processing a substrate 512, and a UV light chamber 520 for housing a UV light source 522. The apparatus 500 includes a substrate holder 514 for supporting the substrate 512 in the process chamber 510. The apparatus 500 may include one or more heating elements 516 for controlling a temperature of the substrate 512. In some implementations, the substrate holder 514 may clamp or hold the substrate 512 so that a backside or frontside of the substrate 512 faces the UV light source 522. Accordingly, the UV light source 522 may be configured to direct UV light to the backside of the substrate 512 in some cases, or the UV light source 522 may be configured to direct UV light to the frontside of the substrate 512 in other cases. Various aspects of the one or more heating elements 516, the substrate holder 514, the substrate 512, the process chamber 510, the UV light chamber 520, and the UV light source 522 in FIG. 5A may be described in accordance with the description of the one or more heating elements 416, the substrate holder 414, the substrate 412, the process chamber 410, the UV light chamber 420, and the UV light source 422 of FIG. 4A.

The substrate 512 may be a bowed semiconductor substrate, where the bowed semiconductor substrate may have a stress-tunable film (not shown) deposited on the backside or frontside of the bowed semiconductor substrate. A bowed semiconductor substrate refers to any semiconductor substrate that has a surface that deviates from a flat reference plane. In particular, a bowed semiconductor substrate may have warpage that exceeds ±300 μm. In some embodiments, the bowed semiconductor substrate may be asymmetrically bowed.

The stress-tunable film may be deposited on the frontside or backside of the substrate 512 with compressive film stress or tensile film stress. The stress-tunable film is configured to undergo substantial stress changes in response to UV exposure, thermal exposure, or combination thereof. Accordingly, the stress-tunable film may be a UV-curable film, a thermally-curable film, or both. The stress-tunable film may include a dielectric material such as an ultralow-k dielectric material. In some implementations, the stress-tunable film includes a nitride, oxide, or doped nitride. Nitrides and oxides may be able to undergo significant stress changes after UV curing. In some examples, the stress-tunable film includes silicon nitride, silicon oxide, silicon oxynitride, or silicon carbonitride. In some embodiments, a thickness of the stress-tunable film is between about 20 nm and about 150 nm, between about 25 nm and about 100 nm, or between about 30 nm and about 100 nm. The thickness of the stress-tunable film is thin enough for full penetration of UV irradiation, and thick enough for inducement of stress on an underlying bowed semiconductor substrate.

In some implementations, the stress-tunable film may be deposited on the substrate 512 using any suitable deposition technique. In some implementations, the stress-tunable film is deposited by a chemical vapor deposition (CVD) such as plasma-enhanced chemical vapor deposition (PECVD). During PECVD, a silicon-containing precursor such as silane may react with one or more reactive gases exposed to plasma to form the stress-tunable film, where the stress-tunable film is a silicon-containing film. For instance, silane (SiH₄) may be flowed into a deposition chamber with ammonia (NH₃) and/or nitrogen (N₂) to deposit silicon nitride. Films deposited by PECVD often contain a considerable amount of hydrogen. The amount of hydrogen in the film can affect the degree of stress in the stress-tunable film. In fact, the amount of hydrogen in the film can influence the degree of stress change that takes place after exposure to elevated temperatures or after exposure to UV light. Specifically, a nitride film such as a silicon nitride film deposited by PECVD may contain Si—H bonds and N—H bonds, in addition to Si—N bonds. Without being limited by any theory, exposing the silicon nitride film to elevated temperatures or UV radiation causes the Si—H bonds to start breaking so that hydrogen atoms are released from the silicon nitride film. As Si—H bonds are broken and hydrogen atoms are released from the film, an internal bonding structure within the silicon nitride film reorganizes. Silicon and nitrogen atoms rearrange and reorganize in the film. This reorganization and rearrangement can induce stress changes in the silicon nitride film, resulting in high stress shifts in response to thermal curing or UV curing.

The apparatus 500 further includes a window 530 positioned between the UV light source 522 and the substrate holder 514. The window 530 may separate the UV light chamber 520 from the process chamber 510. The window 530 may be patterned to define one or more UV-transparent regions 532 and one or more UV-non-transparent regions 534. Transparency as used herein may be defined as transmittance of UV light of about 70% or more, such as about 80% or more, or about 90% or more. That is, an amount of UV light that passes through a thickness of the window 530 in the one or more UV-transparent regions 532 is equal to or greater than about 70%. The one or more UV-non-transparent regions 534 prevent or otherwise limit transmission of UV light through the window 530. In other words, the one or more UV-non-transparent regions 534 obstruct transmission of UV light by reflecting or absorbing UV light, where non-transparency as used herein may be defined as reflection or absorbance of UV light of about 70% or more, such as about 80% or more, or even about 90% or more. This may be accomplished using materials that are opaque or reflective to UV light.

The window 530 is patterned with UV-transparent regions 532 and UV-non-transparent regions 534 to serve as a mask for selective UV exposure of the substrate 512. The UV-non-transparent regions 534 shield or otherwise block UV light from reaching non-targeted regions of the substrate 512, and the UV-transparent regions 532 facilitate transmission of UV light to reach targeted regions of the substrate 512. The window 530 may be configured to overlay the substrate 512. Transparent and non-transparent parts of the window 530 may correspond to regions of the substrate without UV exposure and regions of the substrate with UV exposure, respectively. The transparent and non-transparent parts of the window 530 are positioned, sized, and shaped to address areas of localized bowing and stress in the substrate 512. Thus, the window 530 is patterned according to targeted and non-targeted regions of the substrate 512 for selective UV exposure. In some implementations, the window 530 is sized and shaped to accommodate the size and shape of the substrate 512 to be treated.

During operation, the UV light source 522 emits UV light and passes through the patterned window 530 to selectively cure one or more regions of the stress-tunable film of the substrate 512. The stress-tunable film may be deposited on the substrate 512 with a tensile stress values (e.g., between about +0.1 MPa and about +2000 MPa) or deposited with compressive stress values (e.g., between about −0.1 MPa and about −2000 MPa). By way of an example, a nitrogen-doped silicon carbide film may have an as-deposited stress value of about −400 MPa. In another example, a silicon nitride film may have an as-deposited stress value of about +700 MPa. In response to UV exposure, or both UV and thermal exposure, the stress-tunable film may undergo a stress shift equal to or greater than about 20%, equal to or greater than about 30%, equal to or greater than about 40%, or equal to or greater than about 50%. In some cases, the stress shift may cause the stress-tunable film to change from a tensile film to a compressive film, or vice versa. Portions of the stress-tunable film selectively exposed to UV light undergo stress changes while portions of the stress-tunable film unexposed to UV light avoid stress changes. Exposed portions become more tensile or more compressive after selective UV exposure. This enables the stress-tunable film to locally modulate stress at different portions of the stress-tunable film, thereby mitigating bowing in the bowed semiconductor substrate.

The window 530 is patterned using a material that is non-transparent to UV light. In some implementations, the window 530 is patterned with a metal coating 540 corresponding to the one or more UV-non-transparent regions 534. FIG. 5B shows a cross-sectional schematic illustration of the patterned window 530 of FIG. 5A having a metal coating 540 according to some implementations. The metal coating 540 shields certain areas of the window 530 so that UV light does not pass through the shielded areas. The metal coating 540 may serve to reflect UV light in the UV-non-transparent regions 534, which increases a transmission efficiency of the UV light passing through the UV-transparent regions 532. Specifically, by reflecting the UV light, the UV light may reflect off reflectors positioned throughout the UV light chamber 520, thereby increasing the UV light intensity passing through the UV-transparent regions 532. The metal coating 540 may be positioned directly on a surface of the window 530, on either the surface of the window 530 facing the substrate holder 514 or the surface of the window 530 facing the UV light source 522. In some implementations, the metal coating 540 includes silver, aluminum, or combinations thereof. The metal coating 540 may even be a combination of multiple metal layers. The metal coating 540 may have a thickness sufficient to prevent transmission of UV light. In some implementations, the metal coating 540 has a thickness equal to or greater than 100 nm, such as between about 100 nm and about 1000 nm.

In some implementations, the window is patterned with a ceramic cover 550 corresponding to the one or more UV-non-transparent regions 534. FIG. 5C shows a cross-sectional schematic illustration of the patterned window 530 of FIG. 5A having a ceramic cover 550 according to some implementations. The ceramic cover 550 is designed to shield areas of the window 530 so that UV light does not pass through the shielded areas. The ceramic cover 550 includes a ceramic material that is opaque to UV light. Examples of such ceramic material include but are not limited to aluminum nitride or aluminum oxide. The ceramic cover 550 has openings 552 corresponding to the UV-transparent regions 532 and blocks 554 of the ceramic material corresponding to the UV-non-transparent regions 534. The design of the ceramic cover 550 may be customizable or configured for placement in the apparatus 500 so that the ceramic cover 550 is removably inserted above or below the window 530. In some implementations, the ceramic cover 550 is removably positioned on the window 530. The structure and design of the window 530 may be manufactured independent of the ceramic cover 550. The ceramic cover 550 may have a thickness sufficient for handling and sufficient to prevent transmission of UV light. In some implementations, the ceramic cover 550 may have a thickness equal to or greater than about 0.1 mm, such as between about 0.1 mm and about 10 mm.

In some alternative implementations, the window is patterned with a metal cover (not shown) corresponding to the one or more UV-non-transparent regions 534. Rather than using ceramic material to shield areas of the window 530 so that UV light does not pass through the shielded areas, the metal cover uses metallic material such as aluminum. The metallic material may absorb or reflect the UV light from the UV light source 522.

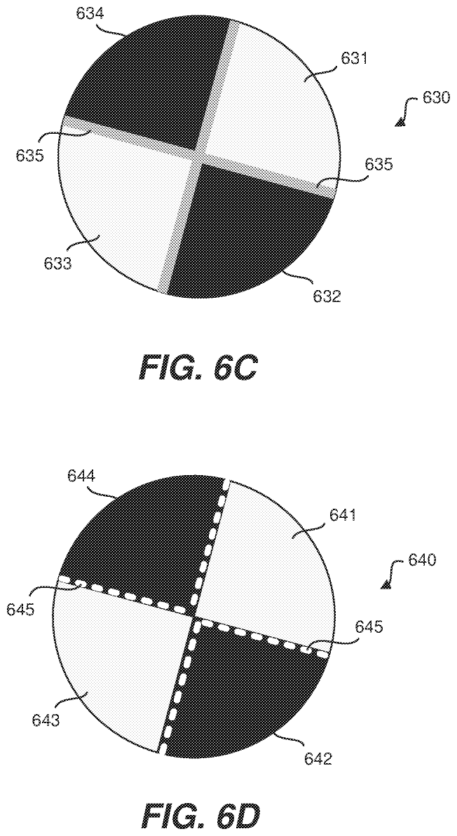

FIG. 6A shows a top view schematic diagram of a patterned window having UV-transparent and UV-non-transparent regions according to some implementations. The patterned window 610 may be any suitable shape for processing a semiconductor substrate. In some implementations, the patterned window 610 is a circular block of material(s). UV light may pass through the patterned window 610 to expose the semiconductor substrate, where the patterned window can be made of a suitable material such as quartz. The patterned window 610 may be defined by multiple zones or regions 611, 612, 613, 614. Regions 611, 613 are “opposite regions” and serve as UV-transparent regions 611, 613, and regions 612, 614 are “opposite regions” and serve as UV-non-transparent regions 612, 614. Regions 612, 614 may also be referred to as shielded regions or covered regions. In some implementations, the UV-non-transparent regions 612, 614 may block or reflect UV light using a metal coating, metal cover, or ceramic cover. In FIG. 6A, the regions 611, 612, 613, 614 are equal in area.

FIG. 6B shows a top view schematic diagram of a patterned window having UV-transparent that occupy a larger surface area than UV-non-transparent regions according to some implementations. The patterned window 620 may be any suitable shape for processing a semiconductor substrate. In some implementations, the patterned window 620 is a circular block of material(s). UV light may pass through the patterned window 620 to expose the semiconductor substrate, where the patterned window can be made of a suitable material such as quartz. The patterned window 620 may be defined by multiple zones or regions 621, 622, 623, 624. Regions 621, 623 are “opposite regions” and serve as UV-transparent regions 621, 623, and regions 622, 624 are “opposite regions” and serve as UV-non-transparent regions 622, 624. In some implementations, the UV-non-transparent regions 622, 624 may block or reflect UV light using a metal coating, metal cover, or ceramic cover. In FIG. 6B, UV-transparent regions 621, 623 occupy a larger surface area than UV-non-transparent regions 622, 624. Specifically, a size and shape of the UV-non-transparent regions 622, 624 can be designed and configured based on a nature of the bowing or shape of the semiconductor substrate being processed. The geometric patterning of the patterned window 620 allows certain areas of the semiconductor substrate to be specifically targeted with UV radiation.

Selective UV exposure creates UV-exposed regions and UV-unexposed regions in the stress-tunable film to mitigate asymmetric bowing, where the stress change can be quite substantial between the UV-exposed and UV-unexposed regions. Where the stress change is too large and sudden, a crest or ridge may form in the substrate being processed. In some instances, even film cracking may occur. By way of an illustration, the as-deposited stress-tunable film may have a stress value of +500 MPa. After selective UV exposure, UV-unexposed regions maintain the stress value of +500 MPa while UV-exposed regions change to a stress value of −500 MPa. The stress shift of 1000 MPa between tensile and compressive regions of the stress-tunable film may be abrupt. However, warpage across the surface of the substrate is generally gradual and smooth, meaning that localized wafer topology changes occur in a smooth, graduated manner rather than in an abrupt, step-wise manner. As a result, stress changes occurring at interfaces between UV-exposed regions and UV-unexposed regions in the stress-tunable film can lead to a crest or ridge in the substrate. It is desired to make stress changes more gradual and smoother at interfaces between UV-exposed and UV-unexposed regions of the stress-tunable film.

In some implementations, the window (e.g., window 530) may be further patterned with one or more transition regions for partial or limited transmission of UV light through the one or more transition regions of the window. For example, a transition area may permit about 50% transmittance of UV light, while UV-transparent regions may permit over 90% transmittance of UV light and UV-non-transparent regions may permit less than 5% transmittance of UV light. The one or more transition regions provide partial or reduced UV exposure of corresponding transition areas of the stress-tunable film. That way, the corresponding transition areas of the stress-tunable film undergo a stress shift that is less than the stress shift of the UV-exposed areas of the stress-tunable film. The corresponding transition areas of the stress-tunable film provide an interface between the UV-exposed areas and UV-unexposed areas of the stress-tunable film so that a stress change between the UV-exposed areas and UV-unexposed areas is not as abrupt. This mitigates film cracking and formation of a crest or ridge in the substrate by having the stress change occur more gradually than suddenly.

In some embodiments, the window may include multiple transition regions lining interfaces between UV-transparent regions and UV-non-transparent regions. At least some of the multiple transition regions may allow varying amounts of UV light transmission to provide even more graduated stress changes in corresponding areas of the stress-tunable film. For instance, a first transition region may permit about 60% transmittance of UV light, and a second transition region adjacent to the first transition region may permit about 30% transmittance of UV light. A corresponding first transition area of the stress-tunable film may undergo a greater amount of stress shift than a corresponding second transition area of the stress-tunable film, while the UV-exposed area of the stress-tunable film undergoes the greatest amount of stress shift.

FIG. 6C shows a top view schematic diagram of a patterned window having UV-transparent regions, UV-non-transparent regions, and transition regions that are semi-transparent to UV radiation according to some implementations. Like FIGS. 6A and 6B, the patterned window 630 may be defined by multiple zones or regions 631, 632, 633, 634. Regions 631, 633 are “opposite regions” and serve as UV-transparent regions 631, 633, and regions 632, 634 are “opposite regions” and serve as UV-non-transparent regions 632, 634. The patterned window 630 may be further defined by transition regions 635. The transition regions 635 line an interface between the UV-transparent regions 631, 633 and the UV-non-transparent regions 632, 634. Put another way, the transition regions 635 occupy an area of the patterned window 630 between the UV-transparent regions 631, 633 and the UV-non-transparent regions 632, 634. In FIG. 6C, the transition regions 635 are semi-transparent to UV light. The UV-transparent regions 631, 633 are transparent or at least substantially transparent to UV light, and the UV-non-transparent regions 632, 634 are opaque or reflective to UV light.

In some implementations, the semi-transparency of the transition regions 635 may be achieved using a material that is partially transparent to UV light. By way of an example, such a semi-transparent material may include quartz.

In some implementations, the semi-transparency of the transition regions 635 may be achieved using a reduced thickness of a metal or opaque ceramic material. Ordinarily, a metal coating having a thickness equal to or greater than 100 nm is effective to reflect UV light. The transition regions 635 may include a metal layer having a thickness less than 100 nm to allow partial transmission of UV light. Hence, the transition regions 635 may include UV-non-transparent materials having a reduced thickness relative to the UV-non-transparent regions 632, 634.

FIG. 6D shows a top view schematic diagram of a patterned window having UV-transparent regions, UV-non-transparent regions, and transition regions made of a grid-like mesh according to some implementations. Like FIGS. 6A and 6B, the patterned window 640 may be defined by multiple zones or regions 641, 642, 643, 644. Regions 641, 643 are “opposite regions” and serve as UV-transparent regions 641, 643, and regions 642, 644 are “opposite regions” and serve as UV-non-transparent regions 642, 644. The patterned window 640 may be further defined by transition regions 645. Like FIG. 6C, the transition regions 645 line an interface between the UV-transparent regions 641, 643 and the UV-non-transparent regions 642, 644. In FIG. 6D, the transition regions 645 partially transmit UV light using a grid-like pattern or mesh. The UV-transparent regions 641, 643 are transparent or at least substantially transparent to UV light, and the UV-non-transparent regions 642, 644 are opaque or reflective to UV light.

In some implementations, the grid-like pattern of the transition regions 645 may include a mixture of UV-non-transparent materials and UV-transparent materials. For instance, the grid-like pattern may include metal lines or shapes on quartz material, or may include opaque ceramic lines or shapes on quartz material. That way, UV light passing through the grid-like pattern of the transition regions 645 may be partially reflected or absorbed and partially transmitted.

The stress-tunable film may be deposited on a frontside or backside of the semiconductor substrate. Often, the frontside of the semiconductor substrate contains various circuits, transistors, or other device components. To mitigate bowing in a bowed semiconductor substrate, it may be desirable to deposit the stress-tunable film on the backside of the semiconductor substrate to avoid deposition on circuits, transistors, and other device components.

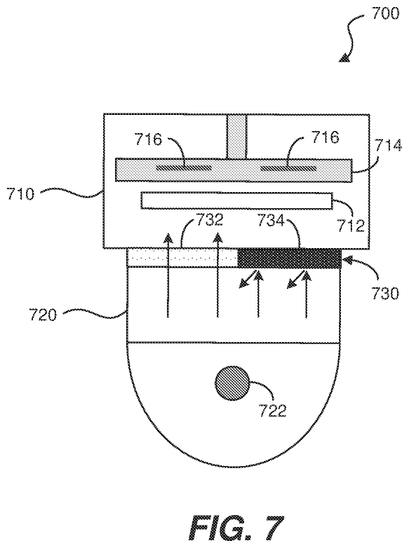

FIG. 7 shows a schematic diagram of an example apparatus for UV backside treatment, the apparatus comprising a patterned window positioned between a UV source and a semiconductor substrate according to some implementations. The apparatus 700 in FIG. 7A may be similar to the apparatus 500 of FIG. 5A except oriented in an upside-down orientation so that a process chamber 710 is shown above a UV light chamber 720. The apparatus 700 includes a process chamber 710 for treating or processing a substrate 712, and a UV light chamber 720 for housing a UV light source 722. The apparatus 700 includes a substrate holder 714 for supporting the substrate 712 in the process chamber 710. In some embodiments, the substrate holder 714 may hold the substrate 712 by the edges and a backside of the substrate 712 may face towards the UV light source 722. In some implementations, the backside of the substrate 712 is not patterned. In some implementations, the backside of the substrate 712 includes a stress-tunable film. The apparatus 700 may include one or more heating elements 716 for controlling a temperature of the substrate 712. Various aspects of the one or more heating elements 716, the substrate holder 714, the substrate 712, the process chamber 710, the UV light chamber 720, and the UV light source 722 in FIG. 7 may be described in accordance with the description of the one or more heating elements 416/516, the substrate holder 414/514, the substrate 412/512, the process chamber 410/510, the UV light chamber 420/520, and the UV light source 422/522 of FIGS. 4A and 5A.

The apparatus 700 further includes a window 730 positioned between the UV light source 722 and the substrate holder 714. The window 730 may separate the UV light chamber 720 from the process chamber 710. The window 730 may be patterned to define one or more UV-transparent regions 732 and one or more UV-non-transparent regions 734. The window 730 is patterned with UV-transparent regions 732 and UV-non-transparent regions 734 to serve as a mask for selective UV exposure of the backside of the substrate 712. This allows targeted regions of the stress-tunable film deposited on the backside of the substrate 712 to undergo stress changes to obtain localized modulated stress, thereby mitigating bowing in the substrate 712. In some implementations, the window 730 is patterned using a metal coating, a ceramic cover, or a metal cover. In some implementations, the window 730 is further patterned with one or more transition regions for partial or reduced transmission of UV light. In FIG. 7, the UV light source 722 is configured to direct UV light to the backside of the substrate 712, where the stress-tunable film is formed on the backside of the substrate 712.

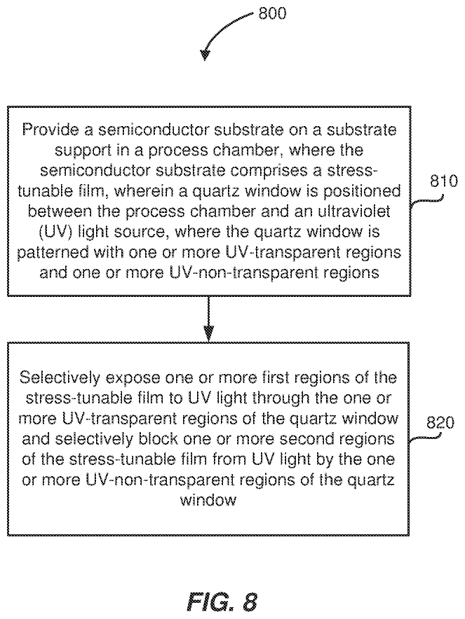

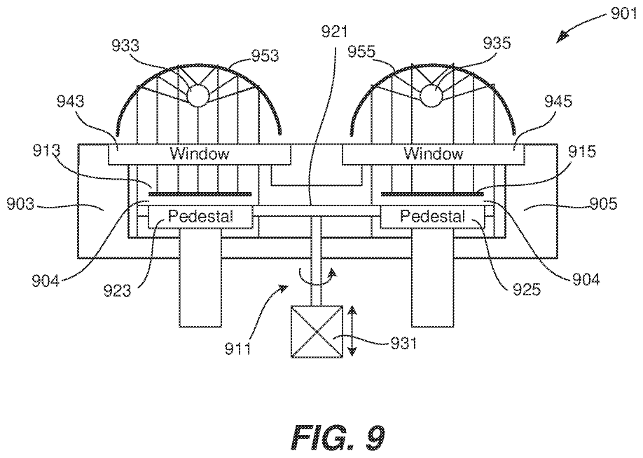

FIG. 8 illustrates a flow diagram of an example method of selective UV exposure according to some implementations. The operations of a process 800 may be performed in different orders and/or with different, fewer, or additional operations. The operations of the process 800 may be performed using an apparatus for UV treatment in FIG. 5A, FIG. 7, or FIG. 9. In some implementations, the operations of the process 800 may be implemented, at least in part, according to software stored in one or more non-transitory computer readable media.

At block 810 of the process 800, a semiconductor substrate on a substrate support is provided in a process chamber, where the semiconductor substrate comprises a stress-tunable film. A quartz window is positioned between the process chamber a UV light source, where the quartz window is patterned with one or more UV-transparent regions and one or more UV-non-transparent regions. The semiconductor substrate may be a bowed semiconductor substrate. The bowed semiconductor substrate may be provided in a process chamber for performing at least UV treatment operations. It will be understood, however, that the process chamber may be configured to performing one or both of UV treatment and deposition operations in some implementations. The semiconductor substrate may be a silicon wafer, such as a 200-mm wafer, 300-mm wafer, or a 450-mm wafer, including wafers having one or more layers of material, such as dielectric, conducting, or semiconducting materials deposited thereon. Some of the one or more layers may be patterned. Non-limiting examples of layers include dielectric layers and conducting layers such as silicon oxides, silicon nitrides, silicon carbides, metal oxides, metal nitrides, metal carbides, and metal layers. In various implementations, the semiconductor substrate is patterned.

In some implementations, the semiconductor substrate includes a patterned 3D-NAND structure and one or more etched trenches in the substrate. In some implementations, the semiconductor substrate may be asymmetrically bowed. The bowed semiconductor substrate may have a warpage of about +1000 μm. In some implementations, the bowed semiconductor substrate has a warpage greater than about +300 μm. In some implementations, the bowed semiconductor substrate has a warpage greater than about +300 μm and less than about +1000 μm. The warpage may occur at one or more localized regions of the bowed semiconductor substrate. The warpage may have different values between an x-axis warpage and y-axis warpage. Thus, the warpage may be more significant along one axis compared to another axis.

The stress-tunable film may be deposited on a frontside or backside of the semiconductor substrate. In some implementations, the stress-tunable film is deposited on a backside of the semiconductor substrate. That way, the stress-tunable film avoids being deposited on circuits, transistors, or other device components on the frontside of the semiconductor substrate. The stress-tunable film may serve as a bow compensation layer for mitigating bowing in the semiconductor substrate.

The stress-tunable film may be one or both of a UV-curable film and thermally-curable film. The stress-tunable film may undergo stress changes upon exposure to one or both of UV exposure and thermal exposure. In some implementations, the stress-tunable film can undergo stress shifts equal to or greater than about 20%, equal to or greater than about 30%, equal to or greater than about 40%, or equal to or greater than about 50% upon exposure to UV light and/or elevated temperatures. In some implementations, the stress-tunable film is a UV-curable film that undergoes stress value changes by an amount greater than about 200 MPa, such as an amount between about 200 MPa and about 4000 MPa. This means that as-deposited stress value of the stress-tunable film can change by 200 MPa or more relative to a post-cured stress value of the stress-tunable film. In some cases, the stress-tunable film can change from tensile to compressive, or from compressive to tensile.

In some implementations, the stress-tunable film includes a dielectric material such as an ultralow-k dielectric material. In some implementations, the stress-tunable film includes a nitride, a doped nitride, or an oxide. In some examples, the stress-tunable film includes silicon nitride. In some examples, the stress-tunable film includes silicon carbonitride.

The quartz window between the substrate and the UV light source may be pre-patterned so that UV light may selectively pass through the quartz window. By having the quartz window pre-patterned, this prevents having to introduce a separate component or mask between the substrate and the light source. Preparing a separate component or mask may necessitate additional steps of manufacturing, patterning, and inserting into a space between the substrate and the light source. These additional steps may be time-consuming, cumbersome, and costly. The quartz window is already a component of UV treatment chambers or apparatuses. In some implementations, the quartz window is patterned with a metal coating such as a silver or aluminum coating. The metal coating may correspond to the UV-non-transparent regions of the quartz window. The metal coating may have a thickness equal to or greater than about 100 nm, such as between about 100 nm and about 1000 nm. In some implementations, the quartz window is patterned with a ceramic cover such as an aluminum nitride or aluminum oxide cover. The ceramic cover may correspond to the UV-non-transparent regions of the quartz window. The ceramic cover may have a thickness equal to or greater than about 1 mm, such as between about 1 mm and about 100 mm. In some implementations, the quartz window is patterned with a metal cover such as an aluminum cover. The metal cover may correspond to UV-non-transparent regions of the quartz window. The quartz window may be patterned to permit UV light transmission in the UV-transparent regions and block or reflect UV light in the UV-non-transparent regions. In some implementations, the quartz window may be patterned based on measurements of localized stresses on the semiconductor substrate. Measurements of localized stresses on the semiconductor substrate may be generated from a stress map.

At block 820 of the process 800, one or more first regions of the stress-tunable film is selectively exposed to UV light through the one or more UV-transparent regions of the quartz window, and one or more second regions of the stress-tunable film is selectively blocked from UV light by the one or more UV-non-transparent regions of the quartz window. The one or more first regions correspond to the UV-transparent regions, and the one or more second regions correspond to the UV-non-transparent regions. Selective exposure to UV light of the one or more first regions locally modulates the stress of the stress-tunable film. After locally modulating the stress in various regions of the stress-tunable film, the stress-tunable film serves to mitigate bowing in the semiconductor substrate.

The patterned quartz window selectively blocks off UV exposure so that only certain areas of the semiconductor substrate get exposed to UV radiation. That way, the one or more first regions represent UV-exposed regions that undergo stress changes, while the one or more second regions represent UV-unexposed regions that do not undergo stress changes. The one or more first regions of the stress-tunable film can become more tensile or more compressive in stress compared to the one or more second regions. The stresses in the stress-tunable film after selective UV exposure may be induced to one or more areas of the semiconductor substrate to mitigate bowing in the semiconductor substrate. The local stresses in the stress-tunable film after selective UV exposure can be tuned to achieve local warpage topography.

Without being limited by any theory, changes in stress may develop from removal of hydrogen in the stress-tunable film during UV exposure. This may be observed in PECVD silicon nitride films. The loss of hydrogen and/or shrinkage of voids may result in a volume reduction in the stress-tunable film. However, the constraint of the semiconductor substrate may prevent any lateral shrinkage, thus imposing tensile strain in the exposed regions of the stress-tunable film. In some implementations, selectively exposing the one or more first regions of the stress-tunable film causes such regions to become more tensile in stress compared to non-exposed regions of the stress-tunable film.

In some implementations, changes in stress may occur in the one or more first regions of the stress-tunable film with exposure to elevated temperatures. Without being limited by any theory, the elevated temperatures may cause removal of hydrogen in the stress-tunable film, which may result in a volume reduction in the stress-tunable film. In some implementations, the elevated temperatures may be between about 200° C. and about 800° C. or between about 300° C. and about 700° C. One or more heating elements in the process chamber or substrate support may control a substrate temperature. The one or more heating elements may independently control temperatures by zones or regions so that certain areas of the stress-tunable film may be targeted with the elevated temperatures. Stress changes may be induced in the one or more first regions and/or the one or more second regions of the stress-tunable film in a targeted manner using the one or more heating elements. Stress may be locally modulated in the stress-tunable film using a combination of selective UV exposure and targeted temperature control in some cases.

The degree of local stress modulation in the one or more first regions depends on treatment conditions during UV exposure and/or thermal exposure. In some implementations, the degree of local stress modulation in the one or more first regions depends on time of UV exposure, substrate temperature, intensity of UV radiation, and/or wavelength of UV radiation. However, it will be understood by those skilled in the art that other conditions during UV exposure and/or thermal exposure may be controlled to influence the degree of local stress modulation. Nonetheless, by tuning one or more of the following: (1) time of UV exposure, (2) substrate temperature during UV exposure, (3) intensity of UV exposure, or (4) wavelength of UV exposure, the amount of stress change induced in exposed regions relative to non-exposed regions will vary. For example, longer UV exposure times lead to higher stress values, higher substrate temperatures lead to higher stress values, and higher UV intensities lead to higher stress values. It will be understood that longer UV exposure times, higher substrate temperatures, and higher intensities may reach certain limits in controlling stress values. The aforementioned conditions of UV exposure may be finely tuned to achieve certain levels of local stress modulation in the one or more first regions. The UV light source may be configured to control time of UV exposure (i.e., dose), intensity of UV exposure, and wavelength of UV exposure. A substrate support (i.e., pedestal) may be configured to control substrate temperature.

In some implementations, the time of UV exposure is between about 0.5 minutes and about 120 minutes, between about 1 minute and about 60 minutes, or between about 2 minutes and about 30 minutes. The time or duration of UV exposure is sufficient to observe desirable changes in stress. In some implementations, the temperature during UV exposure is between about 100° C. and about 700° C., between about 150° C. and about 550° C., or between about 200° C. and about 500° C. The temperature regime may be limited by thermal budget constraints, meaning that the substrate temperature during UV treatment is affected by the device and film on the semiconductor substrate. For example, the use of nickel monosilicide (NiSi) layers constrains the substrate temperature to less than 400° C., and the use of nickel platinum silicide (NiPtSi) layers constrains the substrate temperature to less than 480° C. In some implementations, the intensity of UV exposure is between about 1 μW/cm² and about 10 W/cm², between about 10 μW/cm² and about 5 W/cm², or between about 50 μW/cm² and about 1 W/cm². The intensity of the UV radiation may provide sufficient energy to break certain bonds (e.g., Si—H and N—H bonds) in the stress-tunable film.

In some implementations, the one or more first regions of the stress-tunable film may undergo stress changes equal to or greater than about 20%, equal to or greater than about 30%, equal to or greater than about 40%, or equal to or greater than about 50%. The one or more first regions of the stress-tunable film may become more compressive or more tensile than the one or more second regions of the stress-tunable film. It will be understood that the degree of stress modulation in the one or more first regions can depend on the conditions of UV and thermal treatment. Treatment conditions such as time of exposure, substrate temperature, intensity of UV light, and wavelength of UV light may be controlled to vary localized stress modulation.

For example, a silicon carbonitride film may be deposited by PECVD on the semiconductor substrate. The silicon carbonitride film may have an as-deposited compressive stress value of about 400 MPa (−400 MPa). As shown in Table 1 below, first regions of the silicon carbonitride film after selective UV exposure undergo stress changes to become tensile so that the first regions have a tensile stress value of about 400 MPa (+400 MPa). Second regions of the silicon carbonitride film remain at a compressive stress value of about 400 MPa (−400 MPa). In another example, a silicon nitride film may be deposited by PECVD on the semiconductor substrate. The silicon nitride film may have an as-deposited tensile stress value of about 700 MPa (+700 MPa). As shown in Table 1 below, first regions of the silicon nitride film after selective UV exposure undergo stress changes to become more tensile so that the first regions have a tensile stress value of about 1600 MPa (+1600 MPa).

TABLE 1

| | | Stress of First | Stress of Second |
|---|---|---|---|
| | As-deposited | Regions after UV | Regions after UV |
| Film Type | Stress | Curing | Curing |
| Silicon | −400 MPa | +400 MPa | −400 MPa |
| carbonitride | | | |
| Silicon nitride | +700 MPa | +1600 MPa | +700 MPa |

In some implementations, the quartz window is further patterned with one or more transition regions between the one or more UV-transparent regions and the one or more UV-non-transparent regions. The one or more transition regions may be semi-transparent to UV light. While UV light may selectively pass through the one or more UV-transparent regions, UV light may partially pass through the one or more transition regions. For example, the one or more transition regions may have a transmittance of UV light between about 10% and about 90%, between about 20% and about 80%, or between about 25% and about 75%. By reducing transmission of UV light in the one or more transition regions that may line an interface between the UV-transparent regions and UV-non-transparent regions, corresponding areas of the stress-tunable film exposed to the reduced transmission of UV light will undergo reduced amounts of stress change. This prevents an abrupt change in stress between the one or more first regions and the one or more second regions of the stress-tunable film.

In some implementations, the one or more transition regions may include a semi-transparent material. In some implementations, where the UV-non-transparent regions include a metal coating, the one or more transition regions may include a metal layer with a lower thickness. For instance, the one or more transition regions may include a metal layer with a thickness less than about 100 nm. In some implementations, one or more transition regions include a grid-like pattern or mesh of UV-transparent and UV-non-transparent materials.

Disclosed embodiments may be performed in any suitable apparatus or tool. An apparatus or tool may include one or more process stations. Described below are example process stations and tools that may be used in some embodiments.

FIG. 9 illustrates a schematic diagram of an example apparatus for UV curing of a stress-tunable film according to some implementations. The apparatus 901 is appropriate for uses that involve broadband UV sources. The apparatus 901 includes multiple cure stations 903 and 905, each of which accommodates a substrate 913 and 915. The substrates 913 and 915 are located above pedestals 923 and 925. There are gaps 904 between the substrates and the pedestals. The substrate may be supported above the pedestal by an attachment, such as a pin, or floated on gas. Parabolic or planar cold mirrors 953 and 955 are located above broadband UV source sets 933 and 935. UV light from lamp sets 933 and 935 passes through windows 943 and 945. The windows 943 and 945 may be patterned with a metal coating, ceramic cover, metal cover, or other component to provide selective UV exposure to certain regions of the substrates 913 and 915. In alternative embodiments, the substrates 913 and 915 may be supported by the pedestals 923 and 925, respectively. In such embodiments, the lamps may or may not be equipped with cold mirrors. By making full contact with the pedestal, the substrate temperature may be maintained by use of a conductive gas such as helium or a mixture of helium and argon at a sufficient pressure for conductive heat transfer, typically between about 20 and about 760 Torr, or between about 100 and about 600 Torr.

In operation, a substrate enters the chamber at station 903 where a first UV cure operation is performed. The window 943 is provided between the substrate 913 and the UV source set 933, where the window 943 is pre-patterned. Pedestal temperature at station 903 is set to a first temperature, e.g. between about 200° C. and about 500° C., with the UV lamps above station 903 set to a first intensity, e.g., 100% maximum intensity, and first wavelength range, e.g., about 200-800 nm. In some implementations, after curing in station 903 for a sufficient time, the substrate 913 may be transferred to station 905 for further curing or transferred out of the apparatus 901. A second window 945 may be provided between the substrate 915 and the UV source set 935. Pedestal temperature at station 905 is set to a second temperature, which may or may not be the same as the first station and UV intensity is set to a second intensity, e.g. 90% intensity. Additional stations may be used for additional UV curing under different conditions.

In order to irradiate the substrate at different wavelengths or wavelengths ranges while using a broadband UV source, which generates radiation in a broad spectrum, optical components may be used in the radiation source to modulate the part of the broad spectrum that reaches the substrate. For example, reflectors, filters, or combination of both reflectors and filters may be used to subtract a part of the spectrum from the radiation. On reaching the filter, light may be reflected, absorbed into the filter material, or transmitted through.

Long pass filters are interference filters, which provide a sharp cut-off below a particular wavelength. They are useful for isolating specific regions of the spectrum. Long pass filters are used to pass, or transmit, a range of wavelengths and to block, or reflect, other wavelengths on the shorter wavelength side of the passband. Long wavelength radiation is transmitted, while short wavelength radiation is reflected. The region of high transmittance is known as the passband and the region of high reflectance is known as the reject or reflectance band. The roll-off region separates the pass-band and reflect-band. The complexity of long pass filters depends primarily upon the steepness of the transition region and also on the ripple specifications in the passband. In the case of a relatively high angle of incidence, polarization dependent loss may occur. Long pass filters are constructed of hard, durable surface materials covered dielectric coatings. They are designed to withstand normal cleaning and handling.

Another type of filter is UV cut-off filter. These filters do not allow UV transmission below a set value, e.g. 280 nm. These filters work by absorbing wavelengths below the cut-off value. This may be helpful to optimize the desired cure effect

Yet another optical filter that may be used to select a wavelength range is a bandpass filter. Optical bandpass filters are designed to transmit a specific waveband. They are composed of many thin layers of dielectric materials, which have differing refractive indices to produce constructive and destructive interference in the transmitted light. In this way optical bandpass filters can be designed to transmit a specific waveband only. The range limitations are usually dependent upon the interference filters lens, and the composition of the thin-film filter material. Incident light is passed through two coated reflecting surfaces. The distance between the reflective coatings determines which wavelengths will destructively interfere and which wavelengths will be allowed to pass through the coated surfaces. In situations where the reflected beams are in phase, the light will pass through the two reflective surfaces. However, if the wavelengths are out of phase, destructive interference will block most of the reflections, allowing almost nothing to transmit through. In this way, interference filters are able to attenuate the intensity of transmitted light at wavelengths that are higher or lower than the desired range.

In addition to changing the wavelengths by altering the radiation that reaches the substrate, radiation wavelength can also be controlled by modifying the properties of the light generator. Broadband UV source can generate a broad spectrum of radiation, from UV to infrared, but other light generators may be used to emit a smaller spectrum or to increase the intensity of a narrower spectrum. Other light generators may be mercury-vapor lamps, doped mercury-vapor lamps, electrode lamps, excimer lamps, excimer lasers, pulsed Xenon lamps, doped Xenon lamps. Lasers such as excimer lasers can emit radiation of a single wavelength. When dopants are added to mercury-vapor and to xenon lamps, radiation in a narrow wavelength band may be made more intense. Common dopants are iron, nickel, cobalt, tin, zinc, indium, gallium, thallium, antimony, bismuth, or combinations of these. For example, mercury vapor lamps doped with indium emits strongly in the visible spectrum and around 450 nm; iron, at 360 nm; and gallium, at 320 nm. Radiation wavelengths can also be controlled by changing the fill pressure of the lamps. For example, high-pressure mercury vapor lamps can be made to emit wavelengths of 250 nm to 440 nm, particularly 310 nm to 350 nm more intensely. Low-pressure mercury vapor lamps emit at shorter wavelengths.

In addition to changing light generator properties and the use of filters, reflectors that preferentially deliver one or more segments of the lamps spectral output may be used. A common reflector is a cold mirror that allows infrared radiation to pass but reflects other light. Other reflectors that preferentially reflect light of a spectral band may be used. Therefore a substrate may be exposed to radiation of different wavelengths at different stations. Of course, the radiation wavelengths may be the same in some stations.

In FIG. 9, pedestals 923 and 925 are stationary. Indexer 911 lifts and moves each substrate from one pedestal to another between each exposure period. Indexer 911 includes an indexer plate 921 attached to a motion mechanism 931 that has rotational and axial motion. Upward axial motion is imparted to indexer plate 921 to pick up substrates from each pedestal. The rotational motion serves to advance the substrates from one station to another. The motion mechanism then imparts downward axial motion to the plate to put the substrates down on the stations.

Pedestals 923 and 925 are electrically heated and maintained at a desired process temperature. Pedestals 923 and 925 may also be equipped with cooling lines to enable precise substrate temperature control. In an alternate embodiment, a large heater block may be used to support the substrates instead of individual pedestals. A thermally conductive gas, such as helium, is used to effect good thermal coupling between the pedestal and the substrate. In some embodiments, cast pedestals with coaxial heat exchangers may be used.

FIG. 9 shows only an example of a suitable apparatus, and other apparatuses designed for other methods involved in previous and/or subsequent processes may be used. For example, in another embodiment that uses broadband UV source, the substrate support is a carousel. Unlike with the stationary pedestal substrate supports, the substrates do not move relative to the carousel. After a substrate is loaded onto the carousel, the carousel rotates, if necessary, to expose the substrate to light from a UV lamp set. The carousel is stationary during the exposure period. After the exposure period, the carousel rotates to advance each substrate for exposure to the next set of lamps. Heating and cooling elements may be embedded within the rotating carousel. Alternatively the carousel may be in contact with a heater plate or hold the substrates so that they are suspended above a heater plate.

In certain embodiments, the substrates are exposed to UV radiation from focused, rather than, flood lamps. Unlike the broadband source embodiments where the substrates are stationary during exposure (as in FIG. 9), there is relative movement between the substrates and the light sources during exposure to the focused lights as the substrates are scanned. In other embodiments, the substrates may be rotated relative to the light sources to average out any differences in intensity across the substrate.

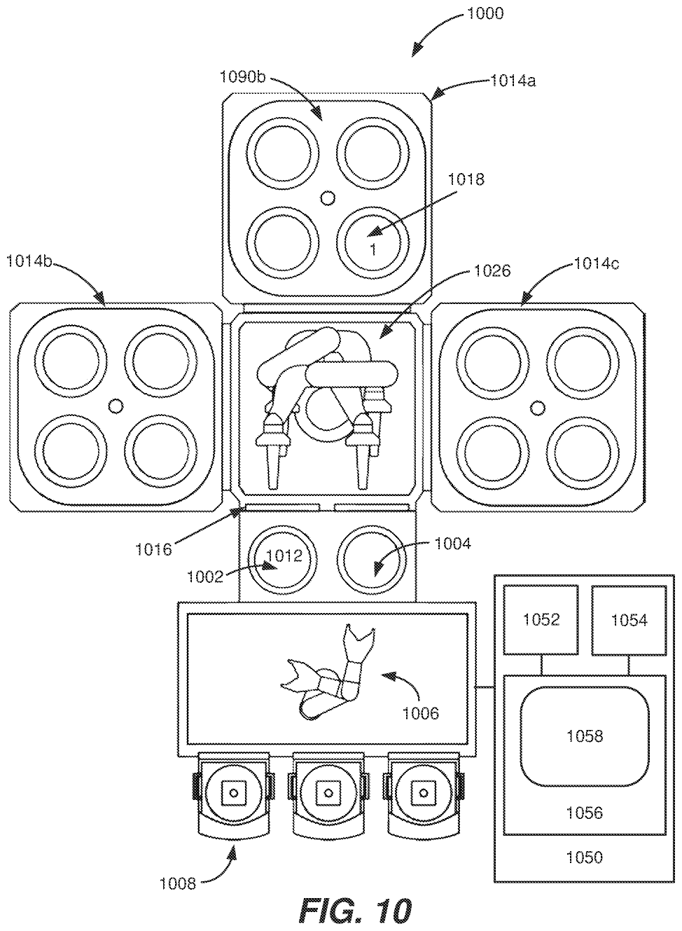

FIG. 10 illustrates a schematic diagram of an example process tool for performing operations for localized stress modulation according to some implementations. In FIG. 5, a multi-station process tool 1000 can include an inbound load lock 1002 and an outbound load lock 1004, either or both of which may comprise a plasma source and/or UV source. A robot 1006, at atmospheric pressure, is configured to move wafers from a cassette loaded through a pod 1008 into inbound load lock 1002 via an atmospheric port (not shown). A wafer or substrate is placed by the robot 1006 on a pedestal 1012 in the inbound load lock 1002, the atmospheric port is closed, and the load lock is pumped down. Where the inbound load lock 1002 includes a remote plasma source, the wafer may be exposed to a remote plasma treatment in the load lock prior to being introduced into one of the processing chambers such as processing chamber 1014a. Where the inbound load lock 1002 includes a UV source, the wafer may be exposed to UV treatment in the load lock prior to being introduced into one of the processing chambers such as processing chamber 1014a. Further, the wafer also may be heated in the inbound load lock 1002 as well, for example, to remove moisture and adsorbed gases. Next, a chamber transport port 1016 to processing chamber 1014a is opened, and another robot 1026 places the wafer into the reactor on a pedestal 1018 of a first station (labeled 1) of processing chamber 1014a shown in the reactor for processing. While the embodiment depicted in FIG. 5 includes load locks, it will be appreciated that, in some embodiments, direct entry of a wafer into a process station may be provided.

Each of the depicted processing chambers, such as processing chamber 1014a, includes four process stations. Each station has a heated pedestal, and gas line inlets. It will be appreciated that in some embodiments, each process station may have different or multiple purposes. For example, a process station may be used to deposit a tensile or compressive material as a part of a bow compensation layer by a suitable deposition technique such as PECVD. Another process station may be used to treat the tensile or compressive material by selective UV curing. In some embodiments, deposition and UV treatment may occur in the same process station. While the depicted processing chamber 1014a includes four stations, it will be understood that a processing chamber according to certain disclosed embodiments may have any suitable number of stations. For example, in some embodiments, a processing chamber may have five or more stations, while in other embodiments a processing chamber may have three or fewer stations. Additionally, while the depicted processing tool 1000 has three processing chambers 1014a, 1014b, and 1014c, it will be understood that a processing tool according to certain disclosed embodiments may have any suitable number of processing chambers.

FIG. 10 depicts an embodiment of a wafer handling system 1090 for transferring wafers within processing chamber 1014a. In some embodiments, wafer handling system 1090 may transfer wafers between various process stations and/or between a process station and a load lock. It will be appreciated that any suitable wafer handling system may be employed. Non-limiting examples include wafer carousels and wafer handling robots. FIG. 10 also depicts an embodiment of a system controller 1050 employed to control process conditions and hardware states of process tool 1000. System controller 1050 may include one or more memory devices 1056, one or more mass storage devices 1054, and one or more processors 1052. Processor 1052 may include a CPU or computer, analog and/or digital input/output connections, stepper motor controller boards, etc.

In some embodiments, system controller 1050 controls all of the activities of process tool 1000. System controller 1050 executes system control software 1058 stored in mass storage device 1054, loaded into memory device 1056, and executed on processor 1052. Alternatively, the control logic may be hard coded in the controller 1050. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 1058 may include instructions for controlling the transfer of wafers into and out of a process chamber, rotating wafers within a process chamber, aligning wafers with the showerhead or quartz window in a process chamber, transfer of wafers into and out of a process chamber, timing of gases out of particular regions of a showerhead, mixture of gases, amount of gas flow out of particular regions of a showerhead, chamber and/or station pressure, backside gas flow pressure out of particular regions of a showerhead, chamber and/or reactor temperature, wafer temperature, bias power, target power levels, RF power levels and type (such as single frequency or dual frequency or high frequency or low frequency), pedestal, chuck and/or susceptor position, UV wavelength, UV dose, UV intensity, and other parameters of a particular process performed by process tool 1000. System control software 1058 may be configured in any suitable way. For example, various process tool component subroutines or control objects may be written to control operation of the process tool components used to carry out various process tool processes. System control software 1058 may be coded in any suitable computer readable programming language.

In some embodiments, system control software 1058 may include input/output control (IOC) sequencing instructions for controlling the various parameters described above. Other computer software and/or programs stored on mass storage device 1054 and/or memory device 1056 associated with system controller 1050 may be employed in some embodiments. Examples of programs or sections of programs for this purpose include a substrate positioning program, a process gas control program, a pressure control program, a heater control program, electrostatic chuck power control program, UV light control program, and a plasma control program.

A substrate positioning program may include program code for process tool components that are used to load the substrate onto pedestal 1018 and to control the spacing between the substrate and other parts of process tool 1000. A UV light control program may include code for controlling UV light conditions (e.g., time, intensity, and wavelength, as described herein). A pressure control program may include code for controlling the pressure in the process station by regulating, for example, a throttle valve in the exhaust system of the process station, a gas flow into the process station, pressure of gas introduced to backside of a wafer during conditioning operations, etc.

A heater control program may include code for controlling the current to a heating unit that is used to heat the substrate for temperature control operations described herein. Alternatively, the heater control program may control delivery of a heat transfer gas (such as helium) to the substrate. A plasma control program may include code for setting RF power levels applied to the process electrodes in one or more process stations in accordance with the embodiments herein. A pressure control program may include code for maintaining the pressure in the reaction chamber in accordance with the embodiments herein.

In some embodiments, there may be a user interface associated with system controller 1050. The user interface may include a display screen, graphical software displays of the apparatus and/or process conditions, and user input devices such as pointing devices, keyboards, touch screens, microphones, etc.

In some embodiments, parameters adjusted by system controller 1050 may relate to process conditions. Non-limiting examples include process gas composition and flow rates, temperature, pressure, plasma conditions (such as RF bias power levels), UV dose, UV intensity, UV wavelength, etc. These parameters may be provided to the user in the form of a recipe, which may be entered utilizing the user interface.

Signals for monitoring the process may be provided by analog and/or digital input connections of system controller 1050 from various process tool sensors. The signals for controlling the process may be output on the analog and digital output connections of process tool 1000. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 1050 may provide program instructions for implementing the above described deposition processes. The program instructions may control a variety of process parameters, such as UV dose, UV intensity, UV wavelength, pressure, temperature, etc. The instructions may control the parameters to operate UV treatment of stress-tunable films according to various embodiments described herein.

The system controller 1050 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 1050.

In some implementations, the system controller 1050 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 1050, depending on the processing conditions and/or the type of system, may be programmed to control any of the processes disclosed herein, including the delivery of processing gases and/or inhibitor gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 1050 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 750 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 1050, in some implementations, may be a part of or coupled to a computer that is integrated with, coupled to the system, otherwise networked to the system, or a combination thereof. For example, the system controller 1050 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 750 receives instructions in the form of data, which specify parameters for each of the processing steps to be performed during one or more operations. It should be understood that the parameters may be specific to the type of process to be performed and the type of tool that the system controller 750 is configured to interface with or control. Thus as described above, the system controller 750 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. An apparatus for selective UV exposure, comprising:
an ultraviolet (UV) light source;
a process chamber comprising:
a substrate support configured to support a semiconductor substrate, wherein the semiconductor substrate comprises a stress-tunable film; and
one or more heating elements configured to control a temperature of the semiconductor substrate; and
a window positioned between the substrate support and the UV light source, wherein the window is patterned with one or more UV-transparent regions for selectively exposing one or more first regions of the stress-tunable film to UV light and one or more UV-non-transparent regions for selectively blocking one or more second regions of the stress-tunable film from UV light.

2. The apparatus of claim 1, wherein the window is patterned with a metal coating corresponding to the one or more UV-non-transparent regions.

3. The apparatus of claim 2, wherein the metal coating comprises silver, aluminum, or combinations thereof.

4. The apparatus of claim 1, wherein the window is patterned with a ceramic cover disposed on the window and corresponding to the one or more UV-non-transparent regions.

5. The apparatus of claim 4, wherein the ceramic cover comprises aluminum nitride or aluminum oxide.

6. The apparatus of claim 1, wherein the window is patterned with a metal cover disposed on the window and corresponding to the one or more UV-non-transparent regions.

7. The apparatus of claim 1, wherein the window is further patterned with one or more transition regions lining an interface between the one or more UV-transparent and the one or more UV-non-transparent regions, wherein the one or more transition regions are semi-transparent to UV light or comprise a grid-like pattern of UV-transparent and UV-non-transparent materials.

8. The apparatus of claim 7, wherein the one or more transition regions comprise a metal layer having a thickness less than about 100 nm.

9. The apparatus of claim 7, wherein the one or more transition regions are configured to provide a more graduated stress change at interfaces between the one or more first regions of the stress-tunable film and the one or more second regions of the stress-tunable film.

10. The apparatus of claim 1, wherein the one or more UV-transparent regions are configured to induce a stress shift in an amount equal to or greater than about 50% in the one or more first regions of the stress-tunable film.

11. The apparatus of claim 1, wherein the UV light source is configured to direct UV light to a backside of the semiconductor substrate, wherein the stress-tunable film is formed on the backside of the semiconductor substrate.

12. The apparatus of claim 1, wherein the UV light source is configured to direct UV light to a frontside of the semiconductor substrate, wherein the stress-tunable film is formed on the frontside of the semiconductor substrate.

13. The apparatus of claim 1, further comprising:
a controller configured with instructions to perform the following operations:
provide the semiconductor substrate in the process chamber; and
selectively expose the one or more first regions of the stress-tunable film to UV light using the window that is patterned so as to locally modulate stress on the stress-tunable film.

14. The apparatus of claim 1, wherein the stress-tunable film comprises silicon nitride, silicon oxide, silicon oxynitride, or silicon carbonitride, and wherein the window comprises quartz.

15. A method of selective UV exposure, comprising:
providing a semiconductor substrate on a substrate support in a process chamber, wherein the semiconductor substrate comprises a stress-tunable film, wherein a quartz window is positioned between the process chamber and an ultraviolet (UV) light source, wherein the quartz window is patterned with one or more UV-transparent regions and one or more UV-non-transparent regions; and
selectively exposing one or more first regions of the stress-tunable film to UV light through the one or more UV-transparent regions of the quartz window and selectively blocking one or more second regions of the stress-tunable film from UV light by the one or more UV-non-transparent regions of the quartz window.

16. The method of claim 15, wherein selectively exposing the one or more first regions of the stress-tunable film comprises locally modulating stress in the one or more first regions of the stress-tunable film.

17. The method of claim 15, wherein the quartz window is patterned with a metal coating corresponding to the one or more UV-non-transparent regions.

18. The method of claim 15, wherein the quartz window is patterned with a ceramic cover or metal cover disposed on the quartz window and corresponding to the one or more UV-non-transparent regions.

19. The method of claim 15, wherein the quartz window is further patterned with one or more transition regions between the one or more UV-transparent and the one or more UV-non-transparent regions, wherein the one or more transition regions are semi-transparent to UV light.

20. The method of claim 19, wherein the one or more transition regions comprise a metal layer having a thickness less than about 100 nm.
